(19) United States
(12) Patent Application Publication
(10) Pub. No.: US 2015/0302921 A1
(43) Pub. Date: Oct. 22, 2015

(54) DEVICE AND METHOD FOR DETERMINING A CELL LEVEL OF A RESISTIVE MEMORY CELL

(71) Applicant: International Business Machines Corporation, Armonk, NY (US)

(72) Inventors: Daniel Krebs, Rueschlikon (CH); Manuel Le Gallo, Rueschlikon (CH); Abu Sebastian, Rueschlikon (CH)

(21) Appl. No.: 14/681,809

(22) Filed: Apr. 8, 2015

(30) Foreign Application Priority Data
Apr. 22, 2014 (GB) 1407089.0

(51) Int. Cl. G11C 13/00; G11C 11/56

(52) U.S. Cl. CPC G11C 13/004; G11C 11/5678; G11C 13/0069

(57) ABSTRACT

A device for determining an actual level of a resistive memory cell having a plurality of programmable levels is suggested. The device comprises an estimator unit and a detection unit. The estimator unit is adapted to receive a time input signal and a temperature input signal and to estimate changes of a read-out signal of the levels of the resistive memory cell based on a time and temperature dependent model of the resistance changes, the received time input signal and the received temperature input signal. The detection unit is adapted to receive an actual read-out signal from the resistive memory cell and the estimated changes from the estimator unit. Further, the detection unit is adapted to determine the actual level of the resistive memory cell based on the received read-out signal and the received estimated changes.

### FIELD OF THE INVENTION

The invention relates to a device and to a method for determining an actual cell level of a resistive memory cell having a plurality of programmable cell levels.

### BACKGROUND

A prominent example for resistive memory cells having a plurality of programmable levels or states is Resistive Random Access Memory (RRAM), particular Phase Change Memory (PCM). PCM is a non-volatile solid-state memory technology that exploits the reversible, thermally-assisted switching of specific chalcogenides between certain states of different electrical conductivity.

PCM is a promising and advanced emerging non-volatile memory technology mainly due to its excellent features including low latency, high endurance, long retention and high scalability. PCM may be considered a prime candidate for Flash replacement, embedded/hybrid memory and storage-class memory. Key requirements for competitiveness of PCM technology may be multi-level cell functionality, in particular for low cost per bit, high-speed read/write operations, in particular for high bandwidth and high endurance. Multilevel functionality, i.e. multiple bits per PCM cell, may be a way to increase storage capacity and thereby to reduce cost.

Multi-level PCM is based on storing multiple resistance levels between a lowest (SET) and a highest (RESET) resistance value. Multiple resistance levels or levels correspond to partial-amorphous and partial-crystalline phase distributions of the PCM cell. Phase transformation, i.e. memory programming, may be enabled by Joule heating. In this regard, Joule heating may be controlled by a programming current or voltage pulse. Storing multiple resistance levels in a PCM cell is a challenging task.

For example, in [1] it is described that the multiple states or levels in a PCM cell are created by varying the programming power, thus creating different crystalline and amorphous fractions within the cell. Further according to [2], in metal-oxide resistive memory devices, multiple states may correspond to variations in the gap between conductive oxygen-vacancy filaments and the electrodes.

As mentioned above, in resistive memory, the fundamental storage unit (referred to generally herein as the “cell”) can be set to a number of different states which exhibit different electrical resistance characteristics. Information is recorded by exploiting the different states to represent different data values. To read recorded data, cell-state is detected via measurements which exploit the differing resistance characteristics to differentiate between possible cell-states. A variety of semiconductor memory technologies employ these basic principles for data storage. Examples include oxide-based memory such as resistive RAM and memristor memory, ionic-transport-based memory, and phase-change memory. The following will focus on phase-change memory (PCM) as a particularly promising technology for future non-volatile memory chips. It is to be understood however, that PCM is only an illustrative application for the invention to be described which can be similarly applied to other resistive memory technologies.

Phase-change memory exploits the reversible switching of certain chalcogenide materials between at least two states with different electrical resistance. In so-called “single-level cell” (SLC) PCM devices, each cell can be set to one of two states, crystalline and amorphous, by application of heat. Each SLC cell can thus store one bit of binary information. However, to satisfy market demand for ever-larger memory capacity and reduce cost per bit, storage of more than one bit per cell is required. To achieve this, it is necessary that a cell can be set to s states where s>2, and that these states can be distinguished on readback via the cell resistance characteristics. Multi-level cell (MLC) operation has been proposed for PCM cells whereby each cell can be set to one of s>2 resistance levels, each corresponding to a different cell state. MLC operation is achieved by exploiting partially-amorphous states of the chalcogenide cell. Different cell states are set by varying the effective volume of the amorphous phase within the chalcogenide material. This in turn varies cell resistance.

To write data to a PCM cell, a voltage or current pulse is applied to the cell to heat the chalcogenide material to an appropriate temperature to induce the desired cell-state on cooling. By varying the amplitude of the voltage or current pulses, different cell-states can be achieved. Reading of PCM cells can be performed using cell resistance to distinguish the different cell-states. The resistance measurement for a read operation is performed in the sub-threshold region of the current-versus-voltage (IN) characteristic of the cell, i.e. in the region below the threshold switching voltage at which a change in cell-state can occur. The read measurement can be performed in a variety of ways, but all techniques rely fundamentally on either voltage biasing and current sensing, or current biasing and voltage sensing. In a simple implementation of the current-sensing approach, the cell is biased at a certain constant voltage level and the resulting cell current is sensed to provide a current-based metric for cell-state. U.S. Pat. No. 7,426,134 B2 discloses one example of a current-sensing technique in which the bias voltage can be set to successive higher levels, and the resulting cell-current compared to successive reference levels, for detecting the different cell-states. US Patent Application Publication No. 2008/0025089 discloses a similar technique in which the cell current is simultaneously compared with different reference levels. In the alternative, voltage-sensing approach, a constant current is passed through the cell and the voltage developed across the cell is sensed to provide a voltage-based metric for cell-state.

Reading of MLC cells is particularly challenging as the read operation involves distinguishing fine differences in cell resistance via the current/voltage measurements. Compared to SLC operation, these fine differences are more readily affected by random noise fluctuations and drift over time, resulting in errors when retrieving stored data. To counteract this loss of data integrity associated with MLC memory, new cell-state metrics, beyond simple resistance, have been proposed. WO2012/029007 discloses a particularly promising metric which is based on the sub-threshold slope of the I/V characteristic of the cell. For example, the metric may be based on the difference between two read measurements of the same cell. This type of metric is less sensitive to noise and drift. In certain embodiments of this measurement technique, the metric is essentially a voltage based metric in the sense that it calls for the measurement of cell voltages (or cell voltage differences) at given bias currents. In general, voltage-based metrics are considered advantageous over current-based metrics, showing less drift over time, less susceptibility to noise, better SNR (signal-to-noise ratio), and allowing more intermediate levels to be packed into one cell. However, the conventional technique for obtaining voltage-based metrics, using current biasing and voltage sensing, is undesirably slow as explained above. This speed penalty associated with the conventional voltage measurement technique means that there is a fundamental conflict between the requirement for a fast random access of the memory and the need for voltage-based metrics supporting high density MLC memory.

Recapitulating, the readout of the cell state may be done via a current-based metric (see references [3] to [7]) or via a voltage-based metric (see references [8] to [12]).

In general, as mentioned above, there is a dependence of the resistance of the cell on temperature variations as well as on the elapsed time. In detail, the amorphization process requires that the temperature within the cell is higher than the melting temperature of the phase-change material. As the molten PCM material is quenched rapidly to a lower temperature, the atomic configurations are frozen into the less ordered amorphous glass-state. Due to the fast quench rates, this glass-state is far from thermal equilibrium leading to structural relaxation which is a function of time and temperature. This structural relaxation and resulting changes to the electrical resistance poses key challenges to the realization of a multi-level resistive memory cell.

Current approaches for countering time and temperature dependent changes of the resistances of the levels of the resistive memory cell are based on using adaptive thresholds (see references [13] and [14]). Another approach may be based on using a non-resistance based metric—a so-called M metric—in order to reduce the fluctuations over time and temperature (see reference [15]). By means of this approach, the fluctuations over time may be reduced by a factor of about 10. However, some fluctuations may still remain, and there is no conventional satisfactory quantitative description of the variation over time and temperature of the M metric.

Accordingly, it is an aspect of the present invention to improve the determining of the actual cell level of a resistive memory cell having a plurality of programmable cell states.

### BRIEF SUMMARY OF THE INVENTION

According to an embodiment of a first aspect, a device for determining an actual level of a resistive memory cell having a plurality of programmable levels is suggested. The device comprises an estimator unit and a detection unit. The estimator unit is adapted to receive a time input signal and a temperature input signal and to estimate changes of a read-out signal of the levels of the resistive memory cell based on a time and temperature dependent model of the resistance changes, the received time input signal and the received temperature input signal. The detection unit is adapted to receive an actual read-out signal from the resistive memory cell and the estimated changes from the estimator unit. Furthermore, the detection unit is adapted to determine the actual level of the resistive memory cell based on the received read-out signal and the received estimated changes.

By using the time and temperature dependent model of the changes of the read-out signal according to embodiments of the invention, the drift of the different memory cell may be captured advantageously. Furthermore, the present device including the estimator unit and the detection unit may be seamlessly incorporated into a read/write apparatus or detection block in a PCM chip.

According to some implementations, the resistive memory cell is a PCM cell (PCM, Phase Change Memory). The PCM cell may be understood as a non-linear resistive device. In particular, the memory cells form a memory array. The present device may provide a faster and more accurate readout scheme specifically optimized for current-based metrics.

In an embodiment, the estimator unit is adapted to provide the estimated changes based on a structural relaxation model and an electrical transport model. In particular, the relaxation model is adapted to model time and temperature dependent changes of energy barriers between the local energy minima. The electrical transport model may use a time and temperature dependent activation energy of each of the levels of the resistive memory cell and a time and temperature dependent evolution of an effective inter-trap distance between neighboring states in the resistive memory cell.

In a further embodiment, the time and temperature dependent model includes a relaxation model being based on transitions between neighboring states of the resistive memory cell corresponding to local energy minima.

The relaxation model may be a relaxation model according to Gibbs (see reference [16]) or according to Egami/Knoll (see reference [17]).

For example, in a programmed amorphous-GST, the atomic positions are frozen into a high-energy state. Relaxation events may occur by overcoming an energy barrier for each relaxation event. The energy skew between the energy levels of the atomic configurations in the amorphous-GST and crystalline-GST may serve as the driving force for these relaxation events. As the relaxation proceeds, the barrier height for further transition gets progressively higher. These drift effects may be captured by the present time and temperature dependent model of the changes of the read-out signal of the resistive memory cell.

In a further embodiment, the relaxation model is generated based on transitions from a stressed state having an initial structural configuration in an amorphous phase to less stressed states having structural configurations in the amorphous phase.

In a further embodiment, the relaxation model is generated based on transitions from a defective state having an initial defect density in the amorphous phase to defective states having lower defect densities in the amorphous phase.

In a further embodiment, the detection unit is adapted to determine the actual level of the resistive memory cell by means of a voltage-based metric, a current-based metric or a differential current-based metric using the received actual read-out signal and the received estimated changes of the read-out signal.

In a further embodiment, the device includes a generator unit for generating the time and temperature dependent model.

In a further embodiment, the device includes a storage unit for storing the time and temperature dependent model.

In a further embodiment, the time input signal includes an actual time of use of the resistive memory cell, an aging time of the resistive memory cell and/or a cycle count corresponding to program and erase cycles of the resistive memory cell.

In a further embodiment, the temperature input signal includes an actual temperature and/or a temperature profile of the resistive memory cell.

In a further embodiment, the device includes a sensor for providing the actual temperature of the resistive memory cell.

In a further embodiment, the time and temperature dependent model for the estimation of changes in the read-out signal is based on a dependence of the read-out signal on a time and temperature dependent activation energy and/or on a time and temperature dependent effective inter-trap distance.

In a further embodiment, the relaxation model is determined based on an assumption of a maximum temperature (Tₘₐₓ) for the resistive memory cell. The determination may be embodied as a calculation or as an assumption.

In a further embodiment, the estimator unit is adapted to calculate an actual time-dependent resistance of each level of the levels of the resistive memory cell in dependence on a time and temperature dependent activation energy of the level and a time and temperature dependent evolution of an order parameter indicating dynamics of structural relaxations of the resistive memory cell described in the relaxation model.

In a further embodiment, the estimator unit is adapted to calculate the actual time-dependent resistance R(t,T) by means of the following two formulas:

$$R ( t , T ) = \frac{{R}_{0} exp ( {E}_{a} ( t , T ) )}{kT}$$

$${E}_{a} ( t , T ) = {E}_{a 0} + α ( {Σ}_{0} - Σ ( t , T ) )$$

where t indicates time, T indicates temperature, R(t,T) indicates the actual resistance, R₀ indicates an initial resistance, α indicates a material parameter of the resistive memory cell, Σ(t,T) indicates a time and temperature dependent order parameter, Σ₀ indicates an initial order parameter, Eₐ(t,T) indicates an activation energy and Eₐ₀ indicates an initial activation energy.

In a further embodiment, the estimator unit is adapted to calculate an actual time and temperature dependent resistance R(t,T) of each level of the levels of the resistive memory cell in dependence on a time and temperature dependent activation energy Eₐ(t,T) of the level and a time and temperature dependent evolution of an estimated order parameter \hat{Σ}(t,T) indicating the dynamics of structural relaxations of the resistive memory cell described in the relaxation model, wherein the estimated order parameter \hat{Σ}((t,T) is estimated based on analytic forms provided under an assumption of a maximum temperature Tₘₐₓ for the resistive memory cell.

In a further embodiment, the estimator unit is adapted to calculate the actual time and temperature dependent resistance R(t,T) by calculating the change in the activation energy Eₐ(t,T) from the changes in the distribution of structural defects in the amorphous phase n(t,T). Also here, an assumption of the maximum temperature Tmax for the resistive memory cell may be used additionally.

In a further embodiment, the estimator unit is adapted to calculate the current-based metric M or the differential current-based metric Mdiff based on an evolution of the total number (n(t,T) of defects derived from the relaxation model, a chosen sub-threshold conduction model depending on the used resistive memory cell and material parameters of the used resistive memory cell.

In a further embodiment, the estimator unit is adapted to calculate the current-based metric M or the differential current-based metric Mdiff based on an evolution of the total number n(t,T) of defects derived from the relaxation model, a chosen sub-threshold conduction model depending on the used resistive memory cell, material parameters of the used resistive memory cell and an assumption of a maximum temperature Tmax for the resistive memory cell.

In a further embodiment, the estimator unit is adapted to calculate the current-based metric M or the differential current-based metric Mdiff based on an evolution of an order parameter Σ(t,T) derived from the relaxation model, a chosen sub-threshold conduction model depending on the used resistive memory cell and material parameters of the used resistive memory cell. Also here, an assumption of the maximum temperature Tmax for the resistive memory cell may be used additionally.

In a further embodiment, the estimator unit is further adapted to derive the evolution of the effective inter-trap distance from a time and temperature dependent evolution of a total number of defects in the resistive memory cell provided by the relaxation model. The total number n(t) of defects may be derived from a structural relaxation model according to Gibbs.

In a further embodiment, the estimator unit is adapted to estimate at least a part of a time and temperature dependent I/V characteristic of the resistive memory cell based on an electrical transport model using a time and temperature dependent activation energy of each of the levels of the resistive memory cell and a time and temperature dependent evolution of an effective inter-trap distance between neighboring states in the resistive memory cell. In particular, the estimator unit is adapted to estimate the whole I/V characteristic of the resistive memory cell. Aspects of the transport model are described in references [18]-[21].

In the following, an example is given for estimating the I/V characteristic of the resistive memory cell as a function of time and temperature (or conductivity as a function of electric field), using a structural relaxation model according to Gibbs. In this example, the evolution of the effective inter-trap distance s(t) and the activation energy Ea(t) are used.

In a first step, an initial distribution of defects is chosen. This is typically fixed for the same type of materials:

N(E, 0)

In a second step, the evolution of the defect distribution with time and temperature is calculated:

$$\frac{d N ( E , t )}{d t} = - κ {e}^{- B / {k}_{B} T} N ( E , t )$$

In a third step, the evolution of the total number n(t) of defects with time and temperature is calculated:

n(t)=∫N(E,t)dE

In a fourth step, the evolution of the effective inter-trap distance s(t) with time and temperature is calculated:

s(t)=n(t)^{-1/2}

In a fifth step, the evolution of the activation energy Ea (t) is calculated:

$${E}_{a} ( t ) = α ( 1 - \frac{n ( t )}{n ( 0 )} ) + {E}_{a 0}$$

Then, the I/V characteristic as a function of time and temperature (or conductivity of the electrical field) is estimated by means of the following formulas:

$$Φ ( r , θ , F , t ) = - eFr cos θ - \frac{{β}^{2}}{4 e} ( \frac{1}{r} + \frac{1}{s ( t ) - r} ) + \frac{{β}^{2}}{es ( t )}$$

$${n}_{c} ( F , t ) = \frac{K}{4 π} {\int }_{0}^{π} exp ( - \frac{{E}_{a} ( t ) - {E}_{PF} ( F , θ , t )}{{k}_{B} T} ) 2 π sin θ d θ$$

$$σ ( F , t ) = e μ {n}_{c} ( F , t )$$

In a further embodiment, the estimator unit is further configured to derive the evolution of the effective inter-trap distance from a time and temperature dependent evolution of an order parameter indicating dynamics of structural relaxation of the resistive memory cell described in the relaxation model. In particular, the order parameter may be derived from a structural relaxation model according to Egami/Knoll.

In the following, an alternative example is given for estimating the I/V characteristic of the resistive memory cell using a structural relaxation model according to Egami/Knoll.

In a first step, an initial state of an order parameter is chosen, which is typically fixed for the same type of materials:

Σ₀=Σ(0)

In a second step, the evolution of the order parameter with time and temperature is calculated:

$$\frac{d Σ ( t )}{d t} = - {v}_{0} {Δ}_{Σ} exp ( - \frac{{E}_{s}}{kT ( t )} ) exp ( \frac{Σ ( t ) {E}_{s}}{kT ( t )} )$$

In a third step, the evolution of effective inter-trap distance s(t) with time and temperature is calculated:

s(t)=Σ(t)^{-1/2}

In a fourth step, the evolution of the activation energy Eₐ (t) for electrical transport is calculated:

$${E}_{a} ( t ) = α ( 1 - \frac{Σ ( t )}{{Σ}_{0}} ) + {E}_{a 0}$$

Then, the IV characteristics as a function of time and temperature (or conductivity as a function of the electrical field) are estimated by means of the following formulas:

$$Φ ( r , θ , F , t ) = - eFr cos θ - \frac{{β}^{2}}{4 e} ( \frac{1}{r} + \frac{1}{s ( t ) - r} ) + \frac{{β}^{2}}{es ( t )}$$

$${n}_{c} ( F , t ) = \frac{K}{4 π} {\int }_{0}^{π} exp ( - \frac{{E}_{a} ( t ) - {E}_{PF} ( F , θ , t )}{{k}_{B} T} ) 2 π sin θ d θ$$

$$σ ( F , t ) = e μ {n}_{c} ( F , t )$$

According to some implementations, the time and temperature dependent activation energy Eₐ(t,T) is calculated based on the structural configurations in the amorphous state Σ(t,T) and/or the defect densities in the amorphous state n(t,T).

According to some implementations, the time and temperature dependent effective inter-trap distance s(t,T) is calculated based on the structural configurations in the amorphous state Σ(t,T) and/or the defect densities in the amorphous state n(t,T).

According to some implementations, the time and temperature dependent activation energy Eₐ(t,T) and the time and temperature dependent effective inter-trap distance s(t,T) are calculated based on the structural configurations in the amorphous state Σ(t,T) and/or the defect densities in the amorphous state n(t,T).

Any embodiment of the first aspect may be combined with any embodiment of the first aspect to obtain another embodiment of the first aspect.

According to an embodiment of a second aspect, a resistive memory device is suggested. The resistive memory device comprises a memory including a plurality of resistive memory cells each having a plurality M of programmable levels, and a read/write apparatus for reading and writing data in the resistive memory cells, wherein the read/write apparatus includes a device of above mentioned first aspect.

According to an embodiment of a third aspect, a method for determining an actual cell state of a resistive memory cell having a plurality of programmable cell states is suggested. The method includes the following steps: receiving a time input signal and a temperature input signal, estimating changes in a read-out signal of the levels of the resistive memory cell based on a time and temperature dependent model of the changes of the read-out signal, the received time input signal and the received temperature input signal, receiving an actual read-out signal from the resistive memory cell, and determining the actual level of the resistive memory cell based on the received actual read-out signal and the estimated changes.

According to an embodiment of a fourth aspect, the invention relates to a computer program comprising a program code for executing at least one step of the method of the third aspect for determining an actual cell state of a resistive memory cell when run on at least one computer.

In the following, exemplary embodiments of the present invention are described with reference to the enclosed figures.

### BRIEF DESCRIPTION OF THE DRAWINGS

FIG. 1 shows an embodiment of a resistive memory device;

FIG. 2 shows an embodiment of a device for determining an actual level of a resistive memory cell;

FIG. 3 shows diagrams illustrating the structural relaxation as a transition from a stressed state to an unstressed state;

FIG. 4 shows a diagram illustrating an embodiment of a transport model;

FIG. 5 shows a diagram illustrating the evolution of the total number of defects in the resistive memory cell;

FIG. 6 shows a diagram illustrating the temperature as a function of time as a reference for FIG. 5;

FIG. 7 shows a diagram illustrating an embodiment of a differential metric in dependence on time;

FIG. 8 shows a diagram illustrating the temperature as a function of time as a reference for FIG. 7;

FIG. 9 shows an embodiment of a sequence of method steps for determining an actual level of a resistive memory cell having a plurality of programmable cell states; and

FIG. 10 shows a schematic block diagram of an embodiment of a system adapted for performing the method for determining an actual level of a resistive memory cell.

Similar or functionally similar elements in the figures have been allocated the same reference signs if not otherwise indicated.

### DETAILED DESCRIPTION OF THE EMBODIMENTS

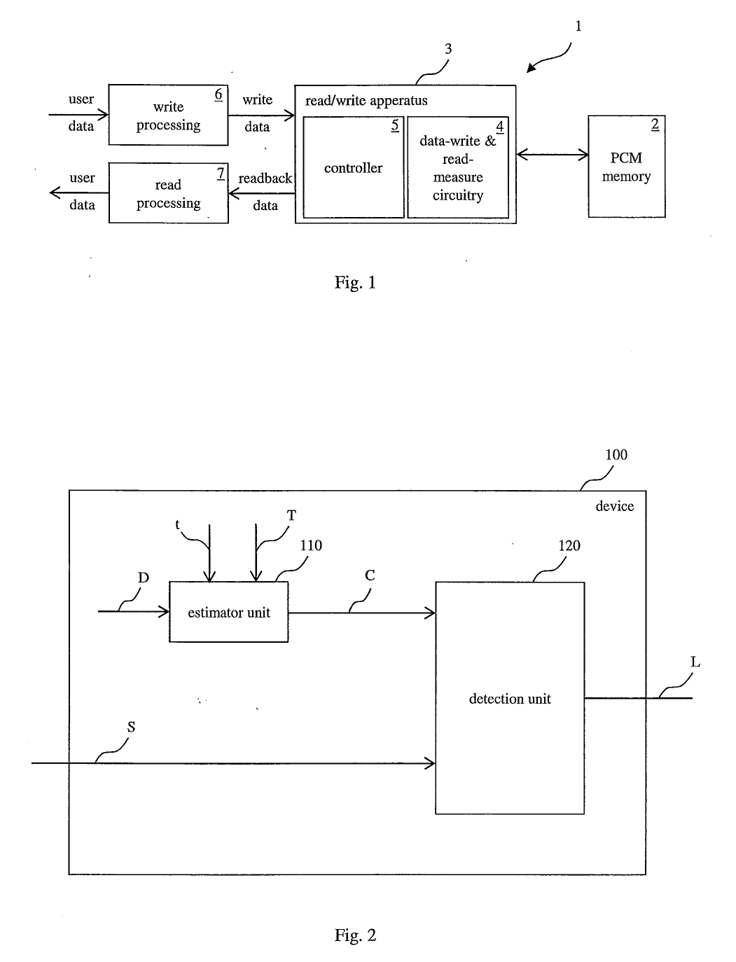

FIG. 1 is a simplified schematic of a resistive memory device 1. The resistive memory device 1 includes a phase-change memory 2 for storing data in one or more integrated arrays of multilevel PCM cells. Though shown as a single block in FIG. 1, in general memory 2 may include any desired configuration of PCM storage units ranging, for example, from a single chip or die to a plurality of storage banks each containing multiple packages of storage chips. Reading and writing of data to memory 2 is performed by read/write apparatus 3. Apparatus 3 includes datawrite and read-measurement circuitry 4 for writing data to the PCM cells and for making cell measurements allowing determination of cell state and hence readback of stored data.

Circuitry 4 can address individual PCM cells for write and read purposes by applying appropriate voltage signals to an array of word and bit lines in memory ensemble 2.

This process is performed in generally known manner except as detailed hereinafter. A read/write controller 5 controls operation of apparatus 3 generally and in particular controls measurement operations in the embodiments to be described, as well as processing of measurements for determining cell state, i.e. level detection, where required. In general, the functionality of controller 5 can be implemented in hardware or software or a combination thereof, though use of hardwired logic circuits is generally preferred for reasons of operating speed. Suitable implementations will be apparent to those skilled in the art from the description herein. As indicated by block 6 in FIG. 1, user data input to device 1 is typically subjected to some form of write-processing, such as coding for error-correction purposes, before being supplied as write data to read/write apparatus 3. Similarly, readback data output by apparatus 3 is generally processed by a read-processing module 7, e.g. performing codeword detection and error correction operations, to recover the original input user data. Such processing by modules 6 and 7 is independent of the cell-state measurement system to be described and need not be discussed further here.

Each of the multilevel cells in memory 2 can be set to one of s resistance levels, where s>2, corresponding to different amorphous/crystalline states of the cell. To write data to memory cells, circuitry 4 applies programming pulses (via cell bit-lines or word-lines depending on whether voltage-mode or current-mode programming is used) of appropriate amplitude to set cells to states representative of the write data. Subsequent reading of a memory cell involves determining the state of the cell, i.e. detecting which of the possible levels that cell is set to. In a read operation of memory device 1, circuitry 4 performs cell measurements from which cell-states can be determined and the stored data recovered.

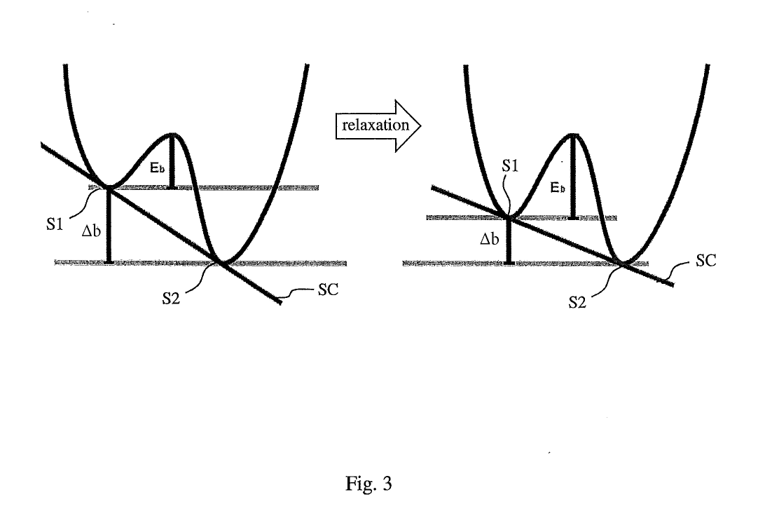

In FIG. 2, a schematic block diagram of an embodiment of device 100 for determining an actual level L of a resistive memory cell having a plurality of programmable levels is depicted. The device 100 may be integrated in the read/write apparatus 3 of FIG. 1.

The device 100 includes an estimator unit 110 and a detection unit 120. The estimator unit 110 is configured to receive a time input signal t and a temperature input signal T and to estimate changes of a read-out signal of the levels of the resistive memory cell based on a time and temperature dependent model D of the changes of the read-out signal, the received time input signal t and the received temperature input signal T.

The time and temperature dependent model D of the changes of the read-out signal is adapted to capture drift effects and may be also called drift model. The time and temperature dependent model D includes a relaxation model being based on transitions between neighboring states of the resistive memory cell corresponding to local energy minima. The drift model D may be a model according to Gibbs (see reference [16]) or according to Egami/Knoll (see reference [17]). The relaxation model is adapted to model time and temperature dependent changes of energy barriers between the local energy minima.

In particular, the relaxation model may be generated based on transitions from a stressed state having an initial structural configuration in an amorphous phase Σ₀ to less stressed states having structural configurations in the amorphous phase Σ(t,T). More details are given with reference to FIG. 3.

Further, the detection unit 120 of the device 100 is configured to receive a read-out signal S (actual read-out signal S) from the resistive memory cell and the estimated resistance changes C from the estimator unit 110. The read-out signal S from the resistive memory cell may be measured from soft information of the level of the cell. Moreover, the detection unit 120 is configured to determine the actual level L of the resistive memory cell based on the received read-out signal S and the received estimated resistance changes C. For example, the detection unit 120 is configured to determine the actual level L of the resistive memory cell by means of a current-based metric M(t) or by means of a differential current-based metric Mdiff(t). As an alternative, the detection unit 120 may use a voltage-based metric.

According to an embodiment, the estimator unit 110 may be adapted to calculate an actual time-dependent resistance R(t) of each level of the levels of the resistive memory cell in dependence on the time-dependent activation energy Ea(t) of the level and the time and temperature dependent evolution of an order parameter Σ(t) indicating dynamics of structural relaxations of the resistive memory cell described by the relaxation model.

In particular, the estimator unit 110 is configured to calculate the actual time-dependent resistance R(t) by means of the following two formulas:

$$R ( t ) = \frac{{R}_{0} exp ( {E}_{a} ( t ) )}{kT}$$

$${E}_{a} ( t ) = {E}_{a 0} + α ( {Σ}_{0} - Σ ( t ) )$$

where t indicates time, T indicates temperature, R(t) indicates the actual resistance, R0 indicates an initial resistance, Σ(t) indicates a time-dependent order parameter, a indicates a material parameter of the resistive memory cell, Σ₀ indicates an initial order parameter, Eₐ(t) indicates activation energy and Eₐ₀ indicates initial activation energy.

Moreover, as the actual time-dependent resistance R(t), the current based metric M(t) and the differential current-based metric Mdiff(t) may be estimated from both the relaxation model Σ(t) and the evolution of the total number n(t) of defects.

The following example may illustrate the use of the order parameter Σ(t) and its evolution in the drift model D. In this regard, FIG. 3 shows diagrams illustrating the structural relaxation as a transition from the stressed state S1 having a first amorphous phase distribution to an unstressed state S2 having a second amorphous phase distribution. In FIG. 3, SC shows a stressing graph, Δb shows the difference between the two states S1 and S2, and E_{b} shows the energy barrier. For example, amorphous-GST is programmed so that its atomic positions are frozen into the high-energy state S1. Relaxation events may occur by overcoming the energy barrier E_{b} for each relaxation event indicated by the transition from the left side to the right side of FIG. 3. As relaxation proceeds, the barrier height of E_{b} for further transitions gets progressively higher. This is illustrated in the right part of FIG. 3, where E_{b} is significantly higher than in the left part of FIG. 3.

The order parameter Σ(t) is introduced to measure the distance from equilibrium, capturing the dynamics of the structural relaxation. In this regard, a non-linear differential equation with strong temperature dependence is used:

$${E}_{b} = {E}_{s} ( 1 - Σ )$$

$${n}^{-} = {v}_{0} exp ( - \frac{{E}_{b}}{kT} )$$

$${n}^{+} = {v}_{0} exp ( \frac{{E}_{b} + {Δ}_{b}}{kT} )$$

$$\frac{d Σ}{d t} = {Δ}_{Σ} ( {n}^{+} - {n}^{-} ) = {v}_{0} {Δ}_{Σ} exp ( - \frac{{E}_{s}}{kT ( t )} ) exp ( \frac{Σ {E}_{s}}{kT ( t )} ) ( exp ( - \frac{{Δ}_{b} ( Σ )}{kT ( t )} ) - 1 ) \approx - {r}_{0} {Δ}_{Σ} exp ( - \frac{{E}_{s}}{kT ( t )} ) exp ( \frac{Σ {E}_{s}}{kT ( t )} )$$

In general, the present embodiment of the estimator unit 110 may be implemented using the following three forms:

$${Σ}_{0} = Σ ( 0 )$$

$$\frac{d Σ ( t )}{d t} = - {v}_{0} {Δ}_{Σ} exp ( - \frac{{E}_{s}}{kT ( t )} ) exp ( \frac{Σ ( t ) {E}_{s}}{kT ( t )} )$$

$${E}_{a} ( t ) = {E}_{a 0} + a ( {Σ}_{0} - Σ ( t ) )$$

$$R ( t ) = \frac{{R}_{0} exp ( {E}_{a} ( t ) )}{kT}$$

If the temperature varies sufficiently slowly with time, the above formulas can be simplified to:

$${Σ}_{0} = Σ ( 0 )$$

$$Σ ( t ) = \frac{kT}{{E}_{s}} log ( \frac{{τ}_{1}}{{τ}_{o} + t} )$$

$${τ}_{1} = \frac{kT}{{v}_{0} {Δ}_{Σ} {E}_{s}} exp ( \frac{{E}_{s}}{kT ( t )} )$$

$${τ}_{0} = {τ}_{1} exp ( - \frac{{Σ}_{0} {E}_{s}}{kT} )$$

$${R}_{a} ( t ) = {E}_{a 0} + a ( {Σ}_{0} - Σ ( t ) )$$

$$R ( t ) = \frac{{R}_{0} exp ( {E}_{a} ( t ) )}{kT}$$

In another alternative, the estimator unit 110 may be based on the following three equations which use an estimated order parameter \hat{Σ}(t). The estimated order parameter \hat{Σ}(t) is based on analytic forms provided under the assumption of a maximum temperature Tₘₐₓ for the resistive memory cell:

$${Σ}_{0} = Σ ( 0 )$$

$$= \frac{{kT}_{max ( t )}}{{E}_{s}} log ( \frac{{τ}_{1}}{{τ}_{0} + t} ) {T}_{max ( t )} = {max}_{τ < t} T ( τ )$$

$${τ}_{1} = \frac{{kT}_{max ( t )}}{{v}_{a} {Δ}_{I} {E}_{s}} exp ( \frac{{E}_{s}}{{kT}_{max ( τ )}} )$$

$${τ}_{0} = {τ}_{1} exp ( - \frac{{Σ}_{0} {E}_{s}}{{kT}_{max ( τ )}} )$$

$${E}_{a} ( t ) = {E}_{a 0} + α ( {Σ}_{0} - )$$

$$R ( t ) = \frac{{R}_{0} exp ( {E}_{a} ( t ) )}{kT ( t )}$$

In a further alternative of the estimator unit 110, the estimator unit 110 is adapted to estimate the I/V-characteristic of the resistive memory cell based on an electrical transport model and a time and temperature dependent evolution of an effective inter-trap distance s(t) between neighboring states in the resistive memory cell. In the transport model, a subthreshold conduction via trap-limited band transport (excitation and re-trapping) may be used:

$$Φ ( r , θ , F ) = - eFr cos ( θ ) - \frac{{β}^{2}}{4 e} ( \frac{1}{r} + \frac{1}{s - r} ) + \frac{{β}^{2}}{es}$$

$$β = \frac{{e}^{2}}{\sqrt{e {πɛ}_{r} {ɛ}_{0}}}$$

The barrier for excitation depends on the field (Poole-Frenkel), the inter-trap distance s(t) and the jump angle, the bather lowering may be described by:

$${E}_{P F} = {max}_{r ( Φ )} )$$

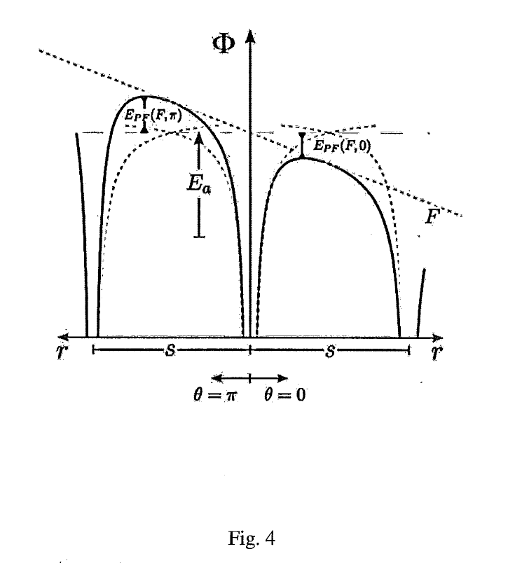

In this regard, FIG. 4 shows a diagram illustrating the transport model which shows the bending of the potential due to field, that the potential barrier depends on the inter-trap distance s(t) and that the emission probability is angle-dependent.

For calculating an enhanced probability for free carriers, the following formula may be used:

$${n}_{o} ( F ) = \frac{K}{4 π} {\int }_{0}^{π} exp ( - \frac{{E}_{a} - {E}_{P F} ( F \cdot θ )}{{k}_{B} T} ) 2 π sin ( θ ) d θ$$

Further, it may be used that the whole I/V-characteristic of the resistive memory cell can be divided into three different regimes, namely Ohmic, Poole and Poole-Frenkel. The transition from Ohmic to Poole is at:

$${F}_{0} = \sqrt{\frac{3 t}{10}} \cdot \frac{2 {k}_{B} T}{es}$$

Furthermore, the transition from Poole to Poole-Frenkel is at

$${F}_{t} = {( \frac{β}{es} )}^{2}$$

Because a full I/V-compensation with the subthreshold conduction model and the structural relaxation model may be fairly complicated and may require some computing power to implement, simplifications may be used based on a prediction of an M metric or an M_{diff}-metric depending on the application that is considered. In the following, it is shown how the different metrics (M, M_{diff}) may be predicted without the need to calculate the full I/V characteristic.

The metrics M and M_{diff} (or Mdiff) may take different forms depending on which subthreshold conduction model is considered.

For example, in reference [15] it is described that the M metric may take the form:

$$M = \frac{V ( {I}_{R} )}{{I}_{R}} {M}_{diff} = \frac{V ( {I}_{R} ) - V ( {I}_{R 0} )}{{I}_{R} - {I}_{R 0}}$$

Furthermore, for Poole-Frenkel conduction, the metrics may take the form:

$$M = \frac{\sqrt{V ( {I}_{R} )}}{{I}_{R}} {M}_{diff} = \frac{√ V ( {I}_{R} ) - √ V ( {I}_{R 0} )}{{I}_{R} - {I}_{R 0}}$$

To provide analytic forms of M and M_{diff}, the subthreshold conduction model may be inverted. The results are the following to analytic formulas for the two metrics M and M_{diff}:

M=A_{M}(nₐ)·(R_{M}(r_{eff})T+Eₐ)n^{1/β}

M_{diff}=A_{Mdiff}(uₐ)Tn^{1/β}

In above equations, the following parameters are used:

A and B: Constants, can depend on uₐ and r_{eff}

uₐ: amorphous thickness (state parameter)

r_{eff}: effective bottom electrode radius, increases when uₐ increases (see reference [15])

Eₐ: activation energy (predicted by Gibbs model)

n: trap density (1/s³, predicted by Gibbs model)

T: Temperature of device

β: “damping” exponent of slope parameter. This depends on the subthreshold model considered. For Poole conduction, one should use theoretically β=3. For Poole-Frenkel, a good agreement is obtained with β=8

Further, to get an analytic form of the structural relaxation model and therefore to get an analytical form for the evolution of n(t), it is assumed that drift only at the maximum temperature is seen by the device:

$$n ( t ) = {n}_{0} ( 1 - \frac{{k}_{B} {T}_{max ( t )}}{{E}_{s}} ln ( {t}_{max} / {t}_{s} ) )$$

$${T}_{max ( t )} = {max}_{T \leq t} T ( τ )$$

tₘₐₓ□: time spent at maximum temperature (i.e. when T(t)≧Tₘₐₓ(t)).

tₛ: time at which the drift starts, set to 1 ns.

n₀ and Eₛ are constants. One may choose n₀=1.2e25 and Eₛ=1.03 eV for GeTe.

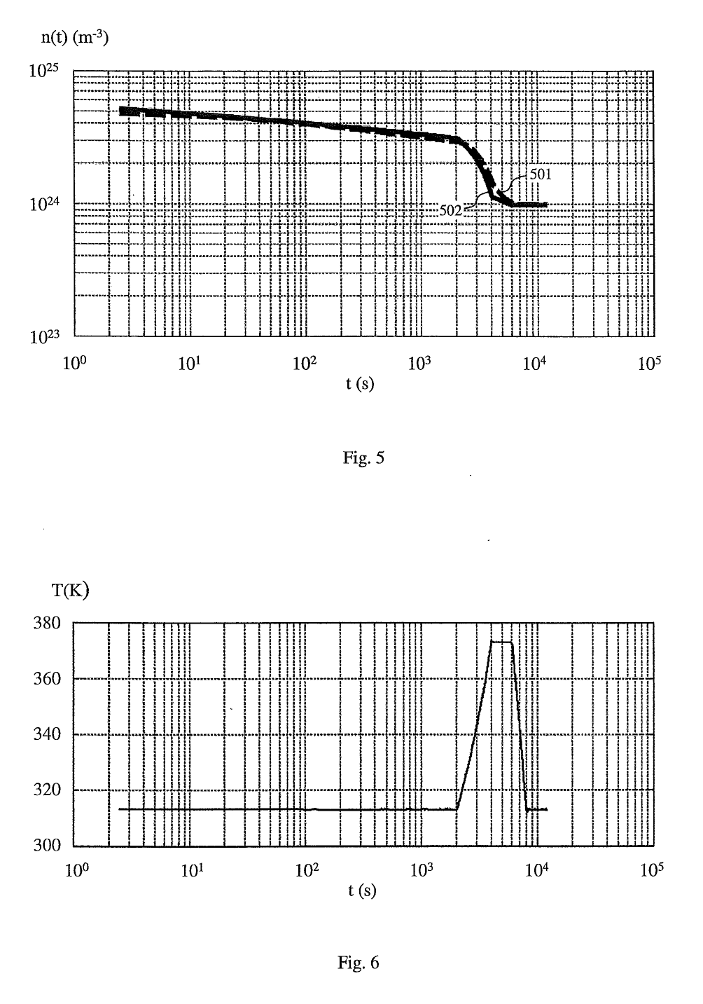

In this regard, FIG. 5 shows a diagram illustrating n(t) as a function of time t, and FIG. 6 shows the temperature T as a function of time t.

In FIG. 5, curve 501 shows the full Gibbs model, wherein curve 502 shows the analytical approximation with Tmax.

Moreover, the following example shows the prediction for M_{diff}:

In a first step, the threshold conduction model Poole or Poole/Frenkel is chosen depending on the device.

$$Poole \text{:} {M}_{diff} = \frac{V ( {I}_{R} ) - V ( {I}_{R 0} )}{{I}_{R} - {I}_{R 0}}$$

$$Poole \text{-} Frenkel \text{:} {M}_{diff} = \frac{\sqrt{V ( {I}_{R} )} - \sqrt{V ( {I}_{R 0} )}}{{I}_{R} - {I}_{R 0}}$$

In a second step, material parameters are fixed governing the evolution of the total defect density:

nₑ,Eₛ,tₛ

In a fourth step, the evolution of the total defect density n(t) is calculated:

$$n ( t ) = {n}_{0} ( 1 - \frac{{k}_{B} {T}_{max ( t )}}{{R}_{s}} ln ( {t}_{max} / {t}_{0} ) )$$

In a fifth step, the change in the M_{diff} metric is calculated upon time and temperature:

M_{diff}=A_{Mdiff}(uₐ)T(t)n(t)^{1/β}

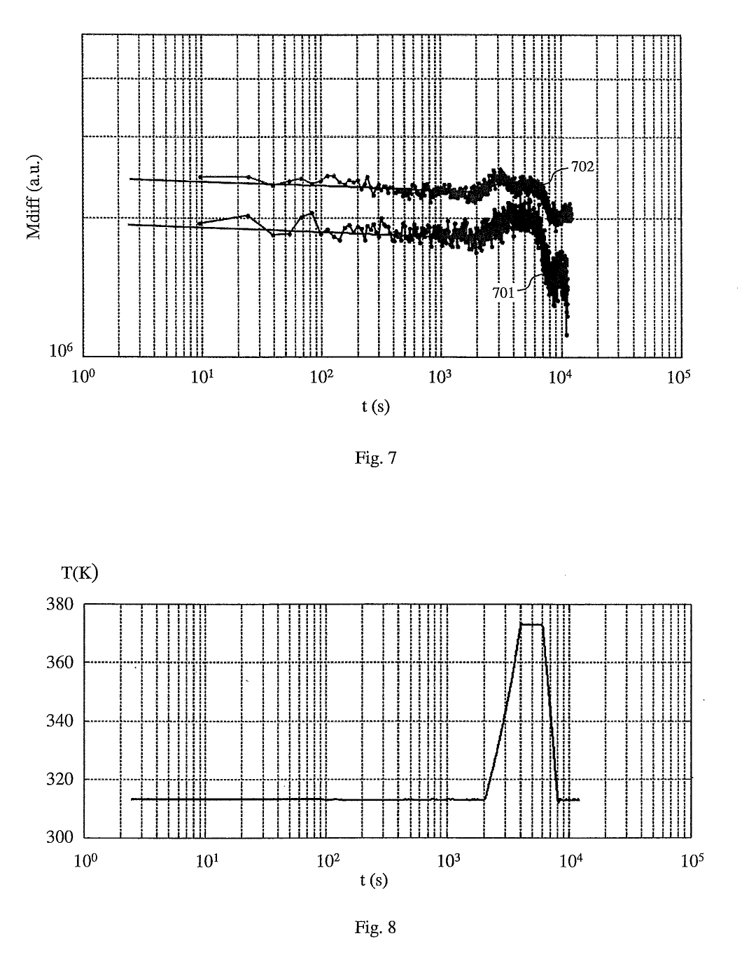

Furthermore, FIGS. 7 and 8 show diagrams illustrating the M_{diff} metric performance. In this regard, FIG. 7 shows M_{diff} in dependence on time t, wherein FIG. 8 shows the temperature T in dependence on time t.

In FIG. 7, curve 701 shows the evolution of a state that was RESET at 8V programming voltage, curve 702 at 10V. FIGS. 7 and 8 show that powerful predictive power is obtained on the full-time and temperature range from above simple analytical formulas. The prediction allows the use of very close memory levels without the risk of overlapping upon time or temperature.

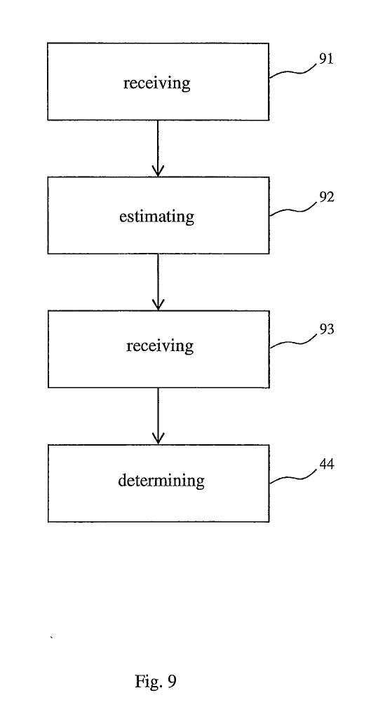

FIG. 9 shows an embodiment of a sequence of method steps for determining an actual level L of a resistive memory cell having a plurality of programmable levels. The method of FIG. 9 has the following steps 91-94.

In step 91, a time input signal t and a temperature input signal T are received, in particular with the write/read apparatus 3 of FIG. 1 or the device 100 of FIG. 2.

In step 92, changes in a read-out signal S of the levels of the resistive memory cell are estimated based on a time and temperature dependent model D of the changes of the read-out signal S, the received time input signal t and the received input temperature T.

In step 93, an actual read-out signal S is received from the resistive memory cell.

In step 94, the actual level of the resistive memory cell is determined based on the received read-out signal S and the estimated changes C.

Computerized devices may be suitably designed for implementing embodiments of the present invention as described herein. In that respect, it may be appreciated that the methods described herein are largely non-interactive and automated. In exemplary embodiments, the methods described herein may be implemented either in an interactive, partly-interactive or non-interactive system. The methods described herein may be implemented in software (e.g., firmware), hardware, or a combination thereof. In exemplary embodiments, the methods described herein are implemented in software, as an executable program, the latter executed by suitable digital processing devices. In further exemplary embodiments, at least one step or all steps of above method of FIG. 9 may be implemented in software, as an executable program, the latter executed by suitable digital processing devices. More generally, embodiments of the present invention may be implemented wherein general-purpose digital computers, such as personal computers, workstations, etc., are used.

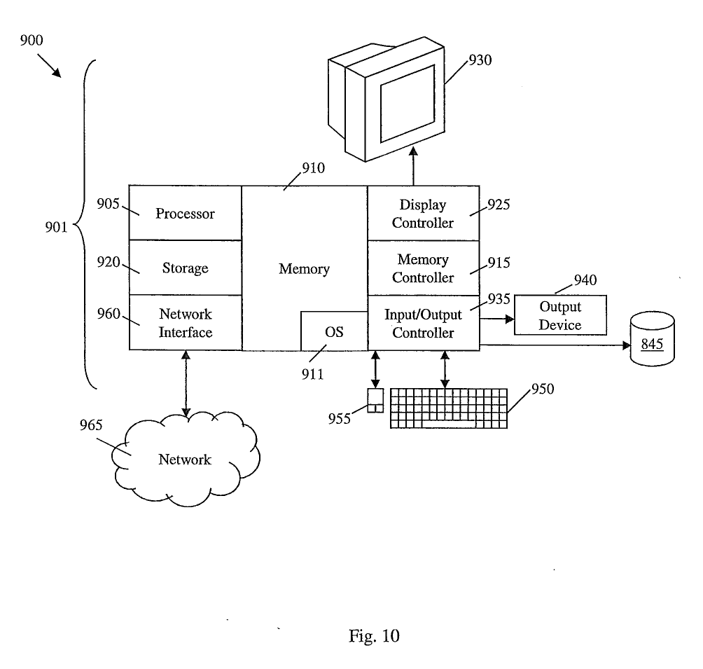

For instance, the system 900 depicted in FIG. 10 schematically represents a computerized unit 901, e.g., a general-purpose computer. In exemplary embodiments, in terms of hardware architecture, as shown in FIG. 10, the unit 901 includes a processor 905, memory 910 coupled to a memory controller 915, and one or more input and/or output (I/O) devices 940, 945, 950, 955 (or peripherals) that are communicatively coupled via a local input/output controller 935. Further, the input/output controller 935 may be, but is not limited to, one or more buses or other wired or wireless connections, as is known in the art. The input/output controller 935 may have additional elements, which are omitted for simplicity, such as controllers, buffers (caches), drivers, repeaters, and receivers, to enable communications. Further, the local interface may include address, control, and/or data connections to enable appropriate communications among the aforementioned components.

The processor 905 is a hardware device for executing software, particularly that stored in memory 910. The processor 905 may be any custom made or commercially available processor, a central processing unit (CPU), an auxiliary processor among several processors associated with the computer 901, a semiconductor based microprocessor (in the form of a microchip or chip set), or generally any device for executing software instructions.

The memory 910 may include any one or combination of volatile memory elements (e.g., random access memory) and nonvolatile memory elements. Moreover, the memory 910 may incorporate electronic, magnetic, optical, and/or other types of storage media. Note that the memory 910 may have a distributed architecture, where various components are situated remote from one another, but may be accessed by the processor 905.

The software in memory 910 may include one or more separate programs, each of which comprises an ordered listing of executable instructions for implementing logical functions. In the example of FIG. 10, the software in the memory 910 includes methods described herein in accordance with exemplary embodiments and a suitable operating system (OS) 911. The OS 911 essentially controls the execution of other computer programs, such as the methods as described herein (e.g., FIG. 9), and provides scheduling, input-output control, file and data management, memory management, and communication control and related services.

The methods described herein may be in the form of a source program, executable program (object code), script, or any other entity comprising a set of instructions to be performed. When in a source program form, then the program needs to be translated via a compiler, assembler, interpreter, or the like, as known per se, which may or may not be included within the memory 910, so as to operate properly in connection with the OS 911. Furthermore, the methods may be written as an object oriented programming language, which has classes of data and methods, or a procedure programming language, which has routines, subroutines, and/or functions.

Possibly, a conventional keyboard 950 and mouse 955 may be coupled to the input/output controller 935. Other I/O devices 940-955 may include sensors (especially in the case of network elements), i.e., hardware devices that produce a measurable response to a change in a physical condition like temperature or pressure (physical data to be monitored). Typically, the analog signal produced by the sensors is digitized by an analog-to-digital converter and sent to controllers 935 for further processing. Sensor nodes are ideally small, consume low energy, are autonomous and operate unattended.

In addition, the I/O devices 940-955 may further include devices that communicate both inputs and outputs. The system 900 may further include a display controller 925 coupled to a display 930. In exemplary embodiments, the system 900 may further include a network interface or transceiver 960 for coupling to a network 965.

The network 965 transmits and receives data between the unit 901 and external systems. The network 965 is possibly implemented in a wireless fashion, e.g., using wireless protocols and technologies, such as WiFi, WiMax, etc. The network 965 may be a fixed wireless network, a wireless local area network (LAN), a wireless wide area network (WAN) a personal area network (PAN), a virtual private network (VPN), intranet or other suitable network system and includes equipment for receiving and transmitting signals.

The network 965 may also be an IP-based network for communication between the unit 901 and any external server, client and the like via a broadband connection. In exemplary embodiments, network 965 may be a managed IP network administered by a service provider. Besides, the network 965 may be a packet-switched network such as a LAN, WAN, Internet network, etc.

If the unit 901 is a PC, workstation, intelligent device or the like, the software in the memory 910 may further include a basic input output system (BIOS). The BIOS is stored in ROM so that the BIOS may be executed when the computer 901 is activated.

When the unit 901 is in operation, the processor 905 is configured to execute software stored within the memory 910, to communicate data to and from the memory 910, and to generally control operations of the computer 901 pursuant to the software. The methods described herein and the OS 911, in whole or in part are read by the processor 905, typically buffered within the processor 905, and then executed. When the methods described herein (e.g. with reference to FIG. 9) are implemented in software, the methods may be stored on any computer readable medium, such as storage 920, for use by or in connection with any computer related system or method.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

More generally, while the present invention has been described with reference to certain embodiments, it will be understood by those skilled in the art that various changes may be made and equivalents may be substituted without departing from the scope of the present invention. In addition, many modifications may be made to adapt a particular situation to the teachings of the present invention without departing from its scope. Therefore, it is intended that the present invention not be limited to the particular embodiments disclosed, but that the present invention will include all embodiments falling within the scope of the appended claims.

### REFERENCE SIGNS

1 memory device
2 memory
3 read/write apparatus
4 data-write and read-measure circuitry
5 controller
6 write processing
7 read processing
100 device
110 estimator unit
120 detection unit
501,502 curves
701,702 curves
91-94 method steps
Eₐ(t) activation energy
E_{b} energy barrier
D drift model
L level
R(t) time-dependent resistance
S read-out signal
S1 stressed state of the resistive memory cell
S2 unstressed state of the resistive memory cell
SC stressing curve
t time input signal
T temperature input signal

### REFERENCES

[1] H.-S. P. Wong et al., Proc. IEEE, 2010
[2] H.-S. P. Wong et al., Proc. IEEE, 2012
[3] T. Happ, M. J. Breitwisch, and H.-I. Lung, Sense circuit for resistive memory, patent number 7426134, United States, 2008.
[4] T. Nirschl and J. Otterstedt, Readout of multi-level storage cells, patent number 20080239833, United States, 2008.
[5] H.-R. Oh, W.-Y. Cho, and C.-K. Kwak, Data read circuit for use in a semiconductor memory and a method therefor, patent number 20060034112, United States, 2006.
[6] R. E. Scheuerlein, T. J. Thorp, and L. G. Fasoli, Method for reading a multi-level passive element memory cell array, patent number 20080025089, United States, 2008.
[7] H.-J. Kim, K.-T. Nam, I.-G. Baek, S.-C. Oh, J.-E. Lee, and J.-H. Jeong, Resistive memory devices including selected reference memory cells, patent number 20070140029, United States, 2007.
[8] U. Frey, A. Pantazi, N. Papandreou, C. Pozidis and A. Sebastian, Determining cell-state in phase-change memory, patent number 20120307554, United States, 2012.
[9] G. Close, C. Hagleitner, A. Pantazi, N. Papandreou, C. Pozidis and A. Sebastian, Cell-state determination in phase-change memory, patent filled under CH920100091US1, United States 2010.
[10] T. D. Happ, H. L. Lung, and T. Nirschl, Current compliant sensing architecture for multilevel phase change memory, patent number 20080165570, United States, 2008.
[11] L.-c. Lin, S.-s. Sheu, and P.-c. Chiang, Sensing circuit of a phase change memory and sensing method thereof, patent number 20080316803, United States, 2008.
[12] G. Close, C. Hagleitner, A. Pantazi, N. Papandreou, C. Pozidis and A. Sebastian, Cell-state measurement in resistive memory, patent number 20120314481, United States, 2012.
[13] N. Papandreou et al.; IMW 2011
[14] H. Pozidis et al.; IMW 2011
[15] A. Sebastian et al.; JAP 2011
[16] M. R. J. Gibbs, J. E. Evetts, J. A. Leake: Activation energy spectra and relaxation in amorphous materials; Journal of Material Science 18 (1983, p. 278-288
[17] A. Knoll, D. Wiesmann, B. Gotsmann, U. Duerig: Relaxation Kinetics of Nanoscale Indents in a Polymer Glass; PHYSICAL REVIEW LETTERS, PRL 102, 117801, 2009
[18] Robert M. Hill: Poole-Frenkel conduction in amorphous solids; Chelsea College of Science and Technology, London
[19] Masayuki Ieda, Goro Sawa, and Sousuke Kato: A Consideration of Poole Frenkel Effect on Electric Conduction in Insulators; J. Appl. Phys. 42, 3737 (1971); doi: 10.1063/1.1659678
[20] J. L. Hartke: The Three-Dimensional Poole-Frenkel Effect; May 1968
[21] Frenkel: On Pre-Breakdown Phenomena in Insulators and Electronic Semi-Conductors; 1938

1. A device (100) for determining an actual level (L) of a resistive memory cell having a plurality of programmable levels, the device (100) comprising:
an estimator unit (110) being adapted to receive a time input signal (t) and a temperature input signal (T) and to estimate changes of a read-out signal of the levels of the resistive memory cell based on a time and temperature dependent model (D) of the changes of the read-out signal, the received time input signal (t) and the received temperature input signal (T), and
a detection unit (120) being adapted to receive an actual read-out signal (S) from the resistive memory cell and the estimated changes (C) from the estimator unit (110) and to determine the actual level (L) of the resistive memory cell based on the received actual read-out signal (S) and the received estimated changes (C).

2. The device of claim 1, wherein the estimator unit (110) is adapted to provide the estimated changes (C) based on a combination of a structural relaxation model and an electrical transport model.

3. The device of claim 1, wherein the time and temperature dependent model (D) includes a structural relaxation model being based on transitions between neighboring states of the resistive memory cell corresponding to local energy minima.

4. The device of claim 1, wherein the structural relaxation model is generated based on transitions from a stressed state having an initial structural configuration in an amorphous phase (Σ₀) to less stressed states having structural configurations in the amorphous phase (Σ(t,T)), or wherein the structural relaxation model is generated based on transitions from a defective state having an initial defect density (n₀) in the amorphous phase to defective states having lower defect densities in the amorphous phase (n(t,T)).

5. The device of claim 1, wherein the detection unit (120) is adapted to determine the actual level (L) of the resistive memory cell by means of a voltage-based metric, a current-based metric or a differential current-based metric using the received actual read-out signal (S) and the received estimated changes (C) of the read-out signal (S).

6. The device of claim 1, wherein the time and temperature dependent model (D) for the estimation of changes (C) in the read-out signal (S) is based on a dependence of the read-out signal (S) on a time and temperature dependent activation energy (Eₐ(t,T)) and/or a time and temperature dependent effective inter-trap distance (s(t,T)) which form at least a part of an electrical transport model.

7. The device of claim 6, wherein the structural relaxation model is approximated based on an assumption of a maximum temperature (Tₘₐₓ) for the resistive memory cell.

8. The device of claim 6, wherein the estimator unit (110) is adapted to calculate the actual time and temperature dependent resistance R(t,T) by means of the following two formulas:
$$R ( t , T ) = \frac{{R}_{0} exp ( {E}_{a} ( t , T ) )}{kT}$$
$${E}_{a} ( t , T ) = {E}_{a 0} \vert a ( {Σ}_{0} - Σ ( t , T ) )$$
where t indicates time, T indicates temperature, R(t,T) indicates the actual resistance, R₀ indicates an initial resistance, α indicates a material parameter of the resistive memory cell, Σ(t,T) indicates a time and temperature dependent order parameter, Σ₀ indicates an initial order parameter, Eₐ(t,T) indicates an activation energy and Eₐ₀ indicates an initial activation energy.

9. The device of claim 2, wherein the estimator unit (110) is adapted to calculate an actual time and temperature dependent resistance (R(t,T)) of each level of the levels of the resistive memory cell in dependence on a time and temperature dependent activation energy (Eₐ(t,T)) of the level and a time and temperature dependent evolution of an estimated order parameter (\hat{Σ}(t,T)) indicating the dynamics of structural relaxation of the resistive memory cell described in the relaxation model, wherein the estimated order parameter (\hat{Σ}((t,T)) is estimated based on analytic forms provided under an assumption of a maximum temperature (Tₘₐₓ) for the resistive memory cell.

10. The device of claim 2, wherein the estimator unit (110) is adapted to calculate the actual time and temperature dependent resistance (R(t,T)) by calculating a change in the activation energy (Eₐ(t,T)) from the changes in the distribution of structural defects in the amorphous phase (n(t,T)).

11. The device of claim 2, wherein the estimator unit (110) is adapted to calculate the current-based metric (M) or the differential current-based metric (M_{diff}) based on an evolution of the total number (n(t,T)) of defects derived from the relaxation model, a chosen sub-threshold conduction model depending on the used resistive memory cell and material parameters of the used resistive memory cell.

12. The device of claim 2, wherein the estimator unit (110) is adapted to calculate the current-based metric (M) or the differential current-based metric (Mdiff) based on an evolution of the total number (n(t,T)) of defects derived from the relaxation model, a chosen sub-threshold conduction model depending on the used resistive memory cell, material parameters of the used resistive memory cell and an assumption of a maximum temperature (Tₘₐₓ) for the resistive memory cell.

13. The device of claim 2,
wherein the estimator unit (110) is adapted to calculate the current-based metric (M) or the differential current-based metric (Mdiff) based on an evolution of an order parameter (Σ(t,T)) derived from the relaxation model, a chosen sub-threshold conduction model depending on the used resistive memory cell and material parameters of the used resistive memory cell.

14. A resistive memory device comprising:
a memory including a plurality of resistive memory cells having a plurality of programmable levels, and
a read/write apparatus for reading and writing data in the resistive memory cells, wherein the read/write apparatus includes a device for determining an actual level (L) of a resistive memory cell having a plurality of programmable levels, the device comprising:
an estimator unit being adapted to receive a time input signal (t) and a temperature input signal (T) and to estimate changes of a read-out signal of the levels of the resistive memory cell based on a time and temperature dependent model (D) of the changes of the read-out signal, the received time input signal (t) and the received temperature input signal (T), and
a detection unit being adapted to receive an actual read-out signal (S) from the resistive memory cell and the estimated changes (C) from the estimator unit and to determine the actual level (L) of the resistive memory cell based on the received actual read-out signal (S) and the received estimated changes (C).

15. A method for determining an actual level (L) of a resistive memory cell having a plurality of programmable levels, the method comprising:
receiving (91) a time input signal (t) and a temperature input signal (T),
estimating (92) changes in a read-out signal (S) of the levels of the resistive memory cell based on a time and temperature dependent model (D) of the changes of the read-out signal, the received time input signal (t) and the received temperature input signal (T),
receiving (93) an actual read-out signal (S) from the resistive memory cell, and
determining (94) the actual level (L) of the resistive memory cell based on the received actual read-out signal (S) and the estimated changes (C).
